(19) United States
(12) Patent Application Publication
(10) Pub. No.: US 2025/0160047 A1
(43) Pub. Date: May 15, 2025

(54) Photodiode

(71) Applicant: LandMark Optoelectronics Corporation, Tainan City (TW)

(72) Inventors: Hung-Wen HUANG, Tainan City (TW); Yung-Chao CHEN, Tainan City (TW); Yi-Hsiang WANG, Tainan City (TW)

(73) Assignee: LandMark Optoelectronics Corporation, Tainan City (TW)

(21) Appl. No.: 18/436,266

(22) Filed: Feb. 8, 2024

(30) Foreign Application Priority Data
Nov. 15, 2023 (TW) 112144104

(51) Int. Cl. H01L 31/0392; H01L 31/0304; H01L 31/109

(52) U.S. Cl. CPC H10F 77/169; H10F 30/222; H10F 77/1248

(57) ABSTRACT

A photodiode includes a substrate, a rectifying layer, a buffer layer, a transition layer, an active layer, and an absorption layer. The substrate has a base lattice constant. The rectifying layer is formed on the substrate, and includes an InGaP layer, an AlGaAs layer, and an InGaAs layer which are stacked on the substrate in that order. The rectifying layer includes a connecting layer that is made of GaAs directly formed on one of the InGaP layer and the InGaAs layer. The buffer layer is made of GaAs and stacked on the rectifying layer. The transition layer is formed on the buffer layer, and includes a plurality of sub-layers that each has a lattice constant greater than the base constant but smaller than a designated constant. The active layer is formed on the transition layer and has the designated constant. The absorption layer is formed on the active layer.

### CROSS-REFERENCE TO RELATED APPLICATION

This application claims priority to Taiwanese Invention Patent Application No. 112144104, filed on Nov. 15, 2023, and incorporated by reference herein in its entirety.

### FIELD

The disclosure relates to a photodiode, and more particularly to a stress balanced photodiode.

### BACKGROUND

Referring to FIG. 1, a conventional photodetector 1 is fabricated layer by layer via epitaxial growth. More specifically, the conventional photodetector 1 is fabricated via molecular beam epitaxy (MBE), and includes a substrate 11, a buffer layer 12, and a quantum well layer 13, an absorption layer 14, and a window layer 15. In the conventional photodetector 1, the buffer layer 12 is first stacked on the substrate 11, the quantum well layer 13 converts photo energy into electric signals, and is subsequently stacked on the buffer layer 12, the absorption layer 14 absorbs photo energy, and is then stacked on the quantum well layer 13. The window layer 15 is formed on the absorption layer 14 and is used to restrict light input to a light entrance area. When the photo detector 1 is in operation, light rays enter the light entrance area of the window layer 15 and is incident on the absorption layer 14 which absorbs photo energy and transmits the photo energy to the quantum well layer 13. The quantum well layer 13 is made of different materials to form a bandgap. When electrons in the quantum well layer 13 absorbs enough photo energy to jump energy levels, a corresponding electric signal is generated, thereby allowing the conventional photodetector 1 to detect light.

The buffer layer 12 is formed between the substrate 11 and the quantum well layer 13 and is made of a similar material as the substrate 11. For example, when the substrate is made of n+ type doped gallium arsenide (GaAs), the buffer layer 12 may be made of n type doped gallium arsenide (GaAs). The buffer layer 12 provides a buffer between the substrate 11 and the quantum well layer 13 when fabricating the conventional photodetector 1 via epitaxial growth, especially when there is a bigger difference in composition between the quantum well layer 13 and the substrate 11.

However, even if the conventional photodetector 1 includes the buffer layer 12, because there are large differences between the lattice constants of the different layers, stresses are usually accumulated within the conventional photodetector 1 during the layer by layer epitaxial growth. When the accumulated stresses are overly large, various defects may form in the different layers, and thereby generate enough dark current to affect detection results of the conventional photodetector 1 during operation, or even render the conventional photodetector 1 unusable.

### SUMMARY

Therefore, an object of the disclosure is to provide a photodiode that can alleviate at least one of the drawbacks of the prior art.

According to the disclosure, the photodiode includes a substrate, a rectifying layer, a buffer layer, a transition layer, an active layer, and an absorption layer. The substrate has a base lattice constant. The rectifying layer is formed on the substrate, and includes an InGaP layer, an AlGaAs layer, and an InGaAs layer which are sequentially stacked on the substrate in that order in a direction away from the substrate. The rectifying layer further includes a connecting layer that is made of GaAs, and that is directly formed on one of the InGaP layer and the InGaAs layer. The buffer layer is made of GaAs, and stacked on the rectifying layer. The transition layer is formed on the buffer layer and includes a plurality of sub-layers, each of the sub-layers has a lattice constant that is greater than the base lattice constant but smaller than a designated lattice constant. The active layer is formed on the transition layer, and has the designated lattice constant. The absorption layer is formed on the active layer.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic cross-sectional view of a conventional photodetector.

FIG. 2 is a schematic cross-sectional view illustrating a first embodiment of a photodiode according to the present disclosure.

FIG. 3 is a schematic enlarged view illustrating a rectifying layer of the first embodiment.

FIG. 4 are current over voltage graphs illustrating results from a first experiment comparing the first embodiment to a conventional photodiode.

FIG. 5 are responsivity over wavelength graphs comparing the first embodiment with the conventional photodiode.

FIG. 6 is a schematic enlarged view illustrating a rectifying layer of the second embodiment.

FIG. 7 are current over voltage graphs illustrating results from a second experiment conducted using the second embodiment.

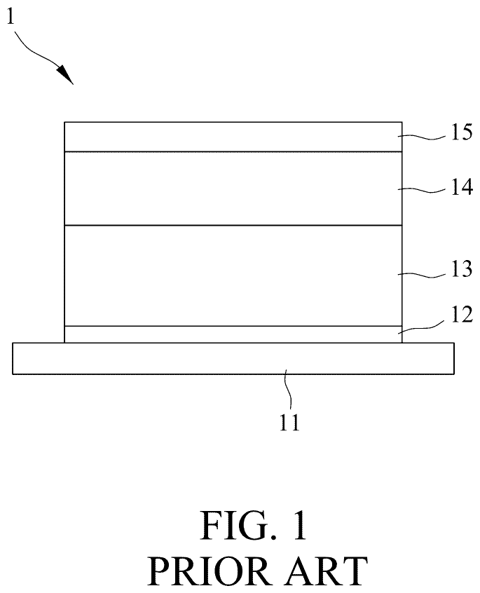

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

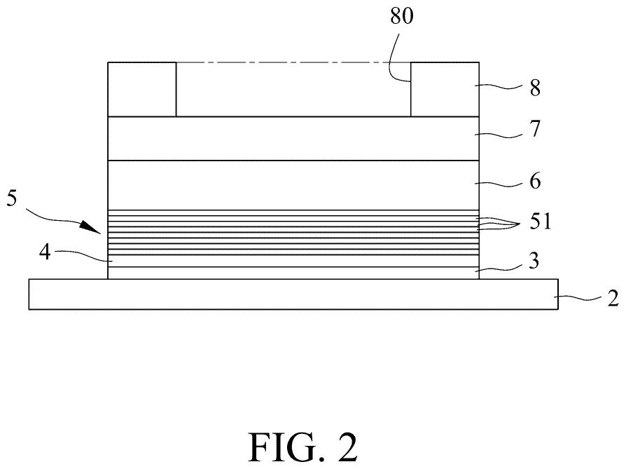

Referring to FIG. 2, a first embodiment of a photodiode according to the present disclosure includes a substrate 2, a rectifying layer 3, a buffer layer 4, a transition layer 5, an active layer 6, an absorption layer 7, and a window layer 8. In this embodiment, the substrate 2 is made of n+ type doped gallium arsenide (GaAs) and has a base lattice constant. The rectifying layer 3 is formed on the substrate 2. The buffer layer 4 is made of n type doped gallium arsenide (GaAs) and stacked on the rectifying layer 3. The transition layer 5 is formed on the buffer layer 4, and includes a plurality of sub-layers 51. Each sub-layer 51 has a lattice constant that is greater than the base lattice constant but smaller than a designated lattice constant. The active layer 6 is formed on the transition layer 5, and has a designated lattice constant. The absorption layer 7 is formed on the active layer 6. The window layer 8 is made of indium gallium phosphide (InGaP), and is formed on the absorption layer 7. The window layer 8 defines a light entry window 80.

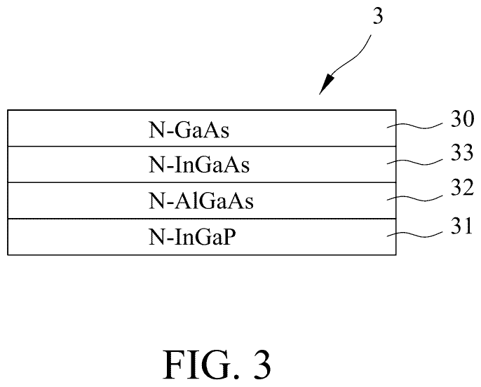

Referring to FIGS. 2 and 3, the rectifying layer 3 includes a first support layer 31, a second support layer 32, a third support layer 33 that are sequentially stacked on the substrate 2 in that order in a direction away from the substrate 2. The rectifying layer 3 further includes a connecting layer 30. The first support layer 31 is made of indium gallium phosphide (InGaP) and is formed directly on the substrate 2 and will be referred to as an InGaP layer 31 hereinafter. The second support layer 32 is made of aluminum gallium arsenide (AlGaAs) and will be referred to as an AlGaAs layer 32 hereinafter. The third support layer 33 is made of indium gallium arsenide (InGaAs) and will be referred as an InGaAs layer 33 hereinafter. The connecting layer 30 is made of gallium arsenide (GaAs) and may be formed directly on one of the InGaP layer 31 and the InGaAs layer 33. As shown in FIG. 3, in the first embodiment, the connecting layer 30 is formed directly on the InGaP layer 33. In this embodiment, because the connecting layer 30 that is formed on the InGaAs layer 33 and that is connected to the buffer layer 4 is made from the same gallium arsenide material (GaAs) as the buffer layer 4, change in lattice constant values between the rectifying layer 3 and the buffer layer 4 may be more gradual and continuous. The InGaP layer 31, the AlGaAs layer 32, and the InGaAs layer 33 are each made of materials selected to have appropriate lattice constants to provide effective support and alleviate stresses accumulation between the substrate 2 and the buffer layer 4 during epitaxial growth, and thereby prevent the formation of defects upon stress relaxation in the photodiode. As described hereinbefore, the substrate 2 is made of n+ type gallium arsenide (n+GaAs), and the buffer layer 4 is made of n type gallium arsenide (n type GaAs).

Additionally, it should be noted that the transition layer 5 may be made of indium gallium phosphide (InGaP) or indium gallium arsenide (InGaAs). The transition layer 5 has an increase in lattice constant in a direction away from the substrate 2. This ensures that the lattice constant between the buffer layer 4 and the active layer 6 will not vary abruptly, and reduce the likelihood of the photodiode accumulating stress during epitaxial growth, and forming defects.

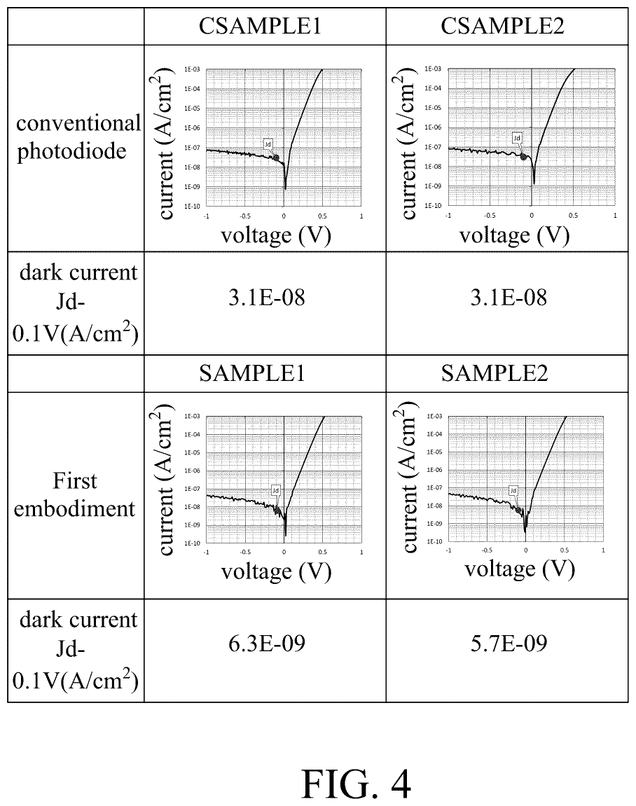

Referring to FIGS. 2, 3 and 4, a conventional photodiode which excludes the rectifying layer 3 is compared with the photodiode of the present disclosure (see FIG. 4). Dark current tests were conducted on two samples of the photodiode of the first embodiment, respectively labelled as SAMPLE1 and SAMPLE2, and two samples of the conventional photodiodes, labelled respectively as CSAMPLE1 and CSAMPLE2. The results of the tests are shown in FIG. 4 and it can be observed that the dark currents of SAMPLE1 and SAMPLE 2 for the photodiodes of the first embodiment are respectively 6.3E-09 and 5.7E-09 at 0.1 V(A/cm²), which are much smaller than the dark current values for the conventional photodiodes; for instance, CSAMPLE2 has a dark current value 3.1E-08 at 0.1V(A/cm²). The results of the experiment show that the first embodiment of the present disclosure has better dark current characteristics compared to a conventional photodiode.

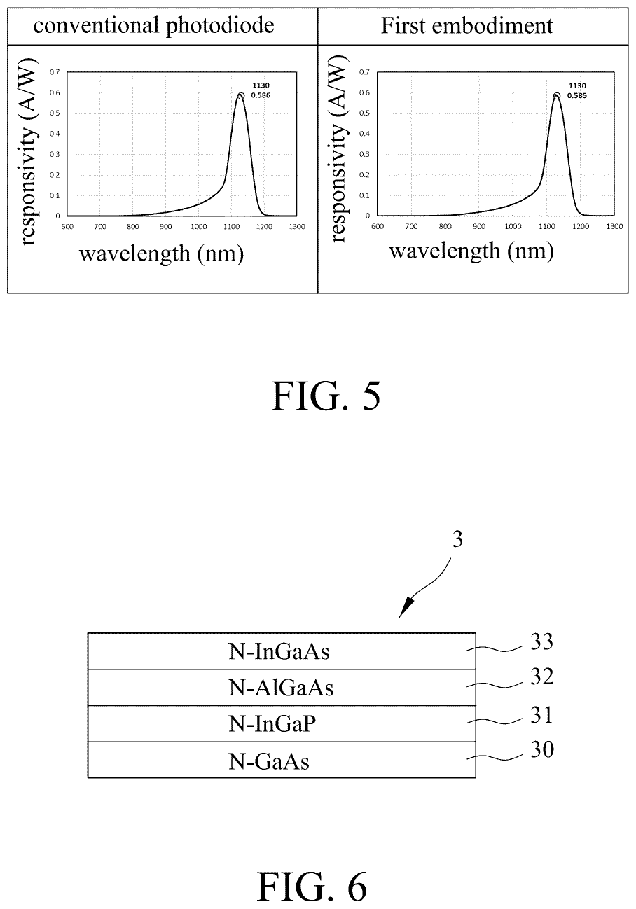

FIG. 5 shows responsivity over wavelength characteristics of SAMPLE2 of the first embodiment and CSAMPLE1/CSAMPLE2 of the conventional photo diode used in the first experiment under normal operation (real-world practical application). SAMPLE 1 and CSAMPLE 1 are implemented as 1130 nm photo-detectors to undergo tests. It can be observed from FIG. 5 that SAMPLE1 of the first embodiment has a responsivity value of 0.585 (A/W) at 1130 nm, which is comparable to the responsivity figures of CSAMPLE1 of the conventional photodiode without the rectifying layer 3 (see FIGS. 2 and 3). This shows that inclusion of the rectifying layer 3 in the first embodiment does not affect the light detecting operation at particular wavelengths, and achieves significantly reduced dark current. Therefore by having less defects according to the present disclosure, it is conceivable that the present disclosure may not only guarantee good production quality but also may have improved photo detection quality and accuracy.

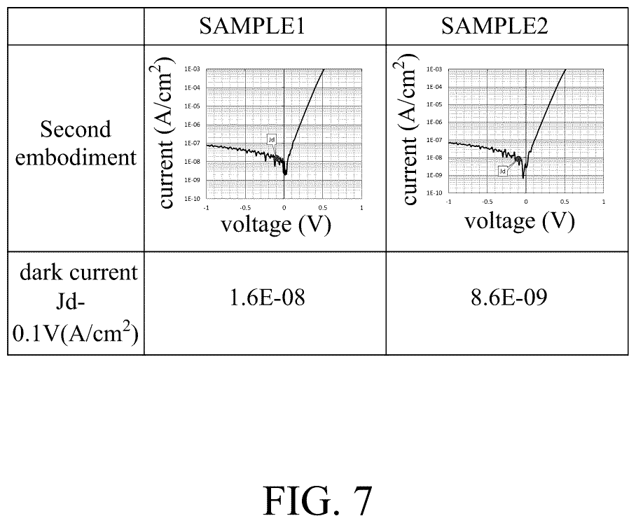

Referring to FIGS. 2 and 6, a second embodiment of the disclosure is generally similar to the first embodiment; however, the difference is that in the second embodiment, the connecting layer 30 is directly formed on the InGaP layer 31, thereby allowing the connecting layer 30 that is made of gallium arsenide (GaAs) to be stacked on the substrate 2 which is made of the same material. Referring to FIGS. 6 and 7, two samples of the second embodiment are respectively labelled SAMPLE1 and SAMPLE2. From the results shown in FIG. 7 it can be observed that SAMPLE1 and SAMPLE2 of the second embodiment has dark current values of 1.6 E-08 and 8.6 E-09 at 0.1 V(A/cm²), respectively, which are both lower than the figures for the dark current of the conventional photodiode samples (CSAMPLE1, CSAMPLE2) shown in FIG. 4. The results show that by connecting the connecting layer 30 to the substrate 2, similar results to the first embodiment may be achieved.

In summary of the above, in the photodiode of the present disclosure, the rectifying layer 3 balances the lattice constants of the photodiode between the substrate 2 and the buffer layer 4. By virtue of the connecting layer in combination with of the InGaP layer 31, the AlGaAs layer 32 and the InGaAs layer 33 which are made of suitable materials having appropriate lattice constants, an effective support can be provided to discourage the accumulation of stresses between the substrate 2 and the buffer layer 4 during the epitaxial growth stage of fabrication, and thereby prevent the formation of defects. This ensures good manufacturing quality of the photodiode; an additional benefit of the photodiode of the disclosure is that dark currents which can affect detection accuracy may be reduced. Moreover, the inclusion of the rectifying layer 3 does not affect detection responsivity at detection wavelengths, thereby allowing the photodiode to have excellent detection capabilities.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A photodiode comprising:
a substrate having a base lattice constant;
a rectifying layer formed on said substrate, and including an InGaP layer, an AlGaAs layer, and an InGaAs layer which are sequentially stacked on said substrate in that order in a direction away from said substrate, said rectifying layer further including a connecting layer that is made of GaAs, and that is directly formed on one of said InGaP layer and said InGaAs layer;
a buffer layer made of GaAs, and stacked on said rectifying layer;
a transition layer formed on said buffer layer, and including a plurality of sub-layers, each of said sub-layers having a lattice constant that is greater than said base lattice constant but smaller than a designated lattice constant;
an active layer formed on said transition layer, and having said designated lattice constant; and
an absorption layer formed on said active layer.

2. The photodiode as claimed in claim 1, wherein said transition layer is made of InGaAs.

3. The photodiode as claimed in claim 1, wherein said transition layer is made of InGaP.

4. The photodiode as claimed in claim 2, wherein said transition layer has an increase in lattice constant in a direction away from said substrate.

5. The photodiode as claimed in claim 3, wherein said transition layer has an increase in lattice constant in a direction away from said substrate.

6. The photodiode as claimed in claim 1, wherein said substrate is made of n+ type GaAs, and said buffer layer being made of n type GaAs.

7. The photodiode as claimed in claim 1, further comprising a window layer formed on said absorption layer, and defining a light entry window.

8. The photodiode as claimed in claim 7, wherein said window layer is made of InGaP.
